(19) United States
(12) Patent Application Publication
(10) Pub. No.: US 2017/0154602 A1
(43) Pub. Date: Jun. 1, 2017

(54) SHIFT REGISTER UNIT, ITS DRIVING METHOD, GATE DRIVER CIRCUIT AND DISPLAY DEVICE

(71) Applicant: BOE TECHNOLOGY GROUP CO., LTD., Beijing (CN)

(72) Inventor: Tuo SUN, Beijing (CN)

(73) Assignee: BOE TECHNOLOGY GROUP CO., LTD., Beijing (CN)

(21) Appl. No.: 15/122,864

(22) PCT Filed: Oct. 29, 2015
(86) PCT No.: PCT/CN2015/093182

§ 371 Date: Aug. 31, 2016

(30) Foreign Application Priority Data
May 28, 2015 (CN) 201510282856.7

(51) Int. Cl. G09G 5/00; G11C 19/28

(52) U.S. Cl. CPC G09G 5/003; G11C 19/28; G09G 2300/0426; G09G 2310/0267; G09G 2310/0286; G09G 2310/0289; G09G 2310/061; G09G 2310/08

(57) ABSTRACT

The present disclosure provides a shift register unit, its driving method, a gate driver circuit and a display device. The shift register unit includes a gate driving signal output end, an output module configured to control the gate driving signal output end to output an invalid signal at an input stage and output a valid signal at an output stage, and a control module configured to turn off the output module at a reset stage.

### CROSS-REFERENCE TO RELATED APPLICATION

The present application claims a priority of the Chinese patent application No.201510282856.7 filed on May 28, 2015, which is incorporated herein by reference in its entirety.

### TECHNICAL FIELD

The present disclosure relates to the field of display technology, in particular to a shift register unit, its driving method, a gate driver circuit and a display device.

### BACKGROUND

A driver for a display device mainly includes a gate driver circuit and a data driver circuit. The gate driver circuit mainly consists of multiple levels of shift register units, and each level of shift register unit is connected to a gate line. Signals are outputted by the multiple levels of shift register units, so as to progressively scan and drive thin film transistors (TFTs) of pixels.

For each shift register unit of the conventional gate driver circuit, a gate driving signal output end is controlled by an output unit so as to output an invalid signal at an input stage, and output a valid signal at an output stage. However, there is no such a control circuit to maintain the output unit in an off state at a reset stage, so the stability of an output waveform from the gate driver circuit will be adversely affected.

To be specific, as shown in FIG. 1, the conventional shift register unit includes an input transistor T1, an output transistor T2, a reset transistor T3, a first control transistor T4, a second control transistor T5, a first capacitor C1 and a second capacitor C2. A gate driving signal Gn-1 from a previous-level shift register unit is applied to a gate electrode of the output transistor T2 through the input transistor T1, to a gate electrode of which a first clock signal CK is applied. In FIG. 1, VGH represents a high level, VGL represents a low level, CKB represents a second clock signal and Gn is a current-level gate driving signal output end. In addition, all transistors in FIG. 1 are P-type transistors. During the operation of the conventional shift register unit, the output transistor T2 needs to be in the off state for a long period of time after it outputs the valid signal. However, the input transistor T1, which controls the gate electrode of the output transistor T2, is controlled by the first clock signal CK, and within a time period where the first clock signal CK is invalid, the gate electrode of the output transistor T2 is in a floating state. In the case of unstable performance, the low-level second clock signal CKB may interfere with the output signal. As a result, the stability of the output waveform, and even the output of the multiple levels of shift register units, will be adversely affected.

### SUMMARY

A main object of the present disclosure is to provide a shift register unit, its driving method, a gate driver circuit and a display device, so as to provide a stable gate driving signal.

In one aspect, the present disclosure provides in some embodiments a shift register unit, including a gate driving signal output end, an output module configured to control the gate driving signal output end to output an invalid signal at an input stage and output a valid signal at an output stage, and a control module configured to turn off the output module at a reset stage.

Optionally, a control end of the output module is connected to an output control node, and the shift register unit further includes an input module configured to input an input signal to the output control node at the input stage and maintain a potential at the output control node at the output stage, and a reset module connected to the output control node and the gate driving signal output end and configured to control the gate driving signal output end to output the invalid signal at the reset stage.

Optionally, the control module includes a control transistor, a gate electrode of which is configured to receive a control signal, a first electrode of which is connected to the output control node, and a second electrode of which is configured to receive a first level. The control signal is used to turn off the control transistor at the input stage and the output stage, and turn on the control transistor at the reset stage.

Optionally, the input module includes an input transistor, a gate electrode of which is configured to receive a first clock signal, a first electrode of which is configured to receive the input signal, and a second electrode of which is connected to the output control node.

Optionally, the output module includes: an output transistor, a gate electrode of which is connected to the output control node, a first electrode of which is connected to the gate driving signal output end, and a second electrode of which is configured to receive a second clock signal with a phase reverse to the first clock signal; and a first capacitor connected between the gate electrode of the output transistor and the gate driving signal output end.

Optionally, the reset module includes: a reset transistor, a gate electrode of which is connected to a reset control node, a first electrode of which is configured to receive the first level, and a second electrode of which is connected to the gate driving signal output end; a first reset control transistor, a gate electrode of which is connected to the output control node, a first electrode of which is configured to receive the first clock signal, and a second electrode of which is connected to the reset control node; a second reset control transistor, a gate electrode of which is configured to receive the first clock signal, a first electrode of which is connected to the reset control node, and a second electrode of which is configured to receive a second level; and a second capacitor, a first end of which is connected to the reset control node, and a second end of which is configured to receive the first level.

Optionally, the first electrode of each transistor is a source electrode and the second electrode of each transistor is a drain electrode, or the first electrode of each transistor is a drain electrode and the second electrode of each transistor is a source electrode.

In another aspect, the present disclosure provides in some embodiments a method for driving the above-mentioned shift register unit, including a step of enabling a control module to turn off an output module at a reset stage.

In yet another aspect, the present disclosure provides in some embodiments a gate driver circuit including multiple levels of the above-mentioned shift register units. Apart from a first-level shift register unit, an input end of a current-level shift register unit is connected to a gate driving signal output end of a previous-level shift register unit.

In still yet another aspect, the present disclosure provides in some embodiments a display device including the above-mentioned gate driver circuit.

According to the shift register unit, its driving method, the gate driver circuit and the display device in the embodiments of the present disclosure, as compared with the related art, it is able to turn off the output module at the reset stage under the control of the control module, thereby to output the gate driving signal in a stable manner.

### BRIEF DESCRIPTION OF THE DRAWINGS

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a circuit diagram of a conventional shift register unit;

FIG. 2 is a schematic view showing a shift register unit according to one embodiment of the present disclosure;

FIG. 3 is another schematic view showing the shift register unit according to one embodiment of the present disclosure;

FIG. 4 is a circuit diagram of the shift register unit according to one embodiment of the present disclosure; and

FIG. 5 is a sequence diagram of the shift register unit according to one embodiment of the present disclosure.

### DETAILED DESCRIPTION OF THE EMBODIMENTS

The present disclosure will be described hereinafter in conjunction with the drawings and embodiments. The following embodiments are for illustrative purposes only, but shall not be used to limit the scope of the present disclosure.

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

In the following, it is clearly and completely described the technical solutions according to the embodiments of the present disclosure. It is obvious that the described embodiments are merely some of all the embodiment of the present disclosure instead of all of the embodiments. All of other embodiments that a person skilled in the art may implement based on the embodiments in the present disclosure without creative work should also fall within the scope of the present disclosure.

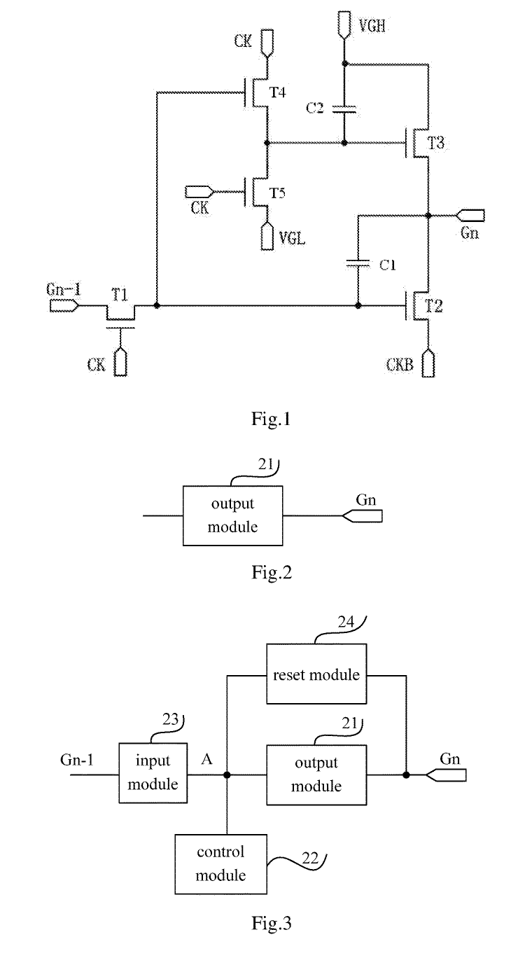

As shown in FIG. 2, the present disclosure provides in some embodiments a shift register unit, which includes a gate driving signal output end Gn, an output module 21 configured to control the gate driving signal output end Gn to output an invalid signal at an input stage and output a valid signal at an output stage, and a control module 22 configured to turn off the output module 21 at a reset stage.

According to the shift register unit in the embodiments of the present disclosure, the output module 21 is turned off at the reset stage under the control of the control module 22, so as to output a gate driving signal in a stable manner.

To be specific, a control end of the output module is connected to an output control node, and the shift register unit further includes an input module configured to input an input signal to the output control node at the input stage and maintain a potential at the output control node at the output stage, and a reset module connected to the output control node and the gate driving signal output end and configured to control the gate driving signal output end to output the invalid signal at the reset stage.

As shown in FIG. 3, the shift register unit includes: the gate driving signal output end Gn; the output module 21, the control end of which is connected to the output control node A, and which is configured to control the gate driving signal output end Gn to output the invalid signal at the input stage and output the valid signal at the output stage; the control module 22 configured to turn off the output module 21 at the rest stage; the input module 23 configured to input an input signal Gn-1 to the output control node A at the input stage and maintain a potential at the output control node A at the output stage; and the reset module 24 connected to the output control node A and the gate driving signal output end Gn and configured to control the gate driving signal output end Gn to output the invalid signal at the reset stage.

For the shift register unit as shown in FIG. 3, at the reset stage, the gate driving signal is an invalid signal under the control of the reset module 24, the input signal Gn-1 (i.e., a gate driving signal from a previous-level shift register unit) is inputted to the output control node A by the input module 23 at the input stage, and the reset module 24 and the output module 21 are controlled in accordance with the potential at the output control node A.

To be specific, the control module includes a control transistor, a gate electrode of which is configured to receive a control signal, a first electrode of which is connected to the output control node, and a second electrode of which is configured to receive a first level. The control signal is used to turn off the control transistor at the input stage and the output stage, and turn on the control transistor at the reset stage.

To be specific, the input module includes an input transistor, a gate electrode of which is configured to receive a first clock signal, a first electrode of which is configured to receive the input signal, and a second electrode of which is connected to the output control node.

To be specific, the output module includes: an output transistor, a gate electrode of which is connected to the output control node, a first electrode of which is connected to the gate driving signal output end, and a second electrode of which is configured to receive a second clock signal with a phase reverse to the first clock signal; and a first capacitor connected between the gate electrode of the output transistor and the gate driving signal output end.

To be specific, the reset module includes: a reset transistor, a gate electrode of which is connected to a reset control node, a first electrode of which is configured to receive the first level, and a second electrode of which is connected to the gate driving signal output end; a first reset control transistor, a gate electrode of which is connected to the output control node, a first electrode of which is configured to receive the first clock signal, and a second electrode of which is connected to the reset control node; a second reset control transistor, a gate electrode of which is configured to receive the first clock signal, a first electrode of which is connected to the reset control node, and a second electrode of which is configured to receive a second level; and a second capacitor, a first end of which is connected to the reset control node, and a second end of which is configured to receive the first level.

The transistors adopted in the embodiments of the present disclosure may be thin film transistors (TFTs), field effect transistors (FETs) or any other elements having an identical characteristic. In the embodiments of the present disclosure, in order to differentiate two electrodes of each transistor except the gate electrode, the first one of the two electrodes may be a source or drain electrode, and the second one of the two electrodes may be a drain or source electrode. In addition, depending on their characteristics, the transistors maybe N-type or P-type transistors. The driver circuit is described by taking the P-type transistors as an example. Of course, the N-type transistors may also be used, which also fall within the scope of the present disclosure.

The shift register unit in the embodiments of the present disclosure will be described hereinafter in more details.

As shown in FIG. 4, in the shift register unit, the input module includes an input transistor T1, a gate electrode of which is configured to receive a first clock signal CK, a first electrode of which is configured to receive an input signal Gn-1 (i.e., a gate driving signal from a previous-level shift register unit), and a second electrode of which is connected to the output control node A.

The output module includes: an output transistor T2, a gate electrode of which is connected to the output control node A, a first electrode of which is connected to the gate driving signal output end Gn of a current-level shift register unit, and a second electrode of which is configured to receive a second clock signal CKB with a phase reverse to the first clock signal CK; and a first capacitor C1 connected between the gate electrode of the output transistor T3 and the gate driving signal output end Gn.

The reset module includes: a reset transistor T3, a gate electrode of which is connected to a reset control node B, a first electrode of which is configured to receive a high level VGH, and a second electrode of which is connected to the gate driving signal output end Gn; a first reset control transistor T4, a gate electrode of which is connected to the output control node A, a first electrode of which is configured to receive the first clock signal CK, and a second electrode of which is connected to the reset control node B; a second reset control transistor T5, a gate electrode of which is configured to receive the first clock signal CK, a first electrode of which is connected to the reset control node B, and a second electrode of which is configured to receive a low level VGL; and a second capacitor C2, a first end of which is connected to the reset control node B, and a second end of which is configured to receive the high level VGH.

The control module includes a control transistor T6, a gate electrode of which is configured to receive a control signal En, a first electrode of which is connected to the output control node A, and a second electrode of which is configured to receive the high level VGH. The control signal En is used to turn off the control transistor T6 at the input stage and the output stage, and turn on the control transistor T6 at the reset stage, so as to maintain the gate electrode of the output transistor T2 at the high level VGH at the reset stage, thereby to turn off the output transistor T2 at the reset stage and output the gate driving signal in a stable manner. In addition, a capacitance of the second capacitor C2 may be reduced due to a continuous direct current supplied thereto, and thereby it is able to reduce a layout area of the shift register unit and facilitate the manufacture of a narrow-bezel display device.

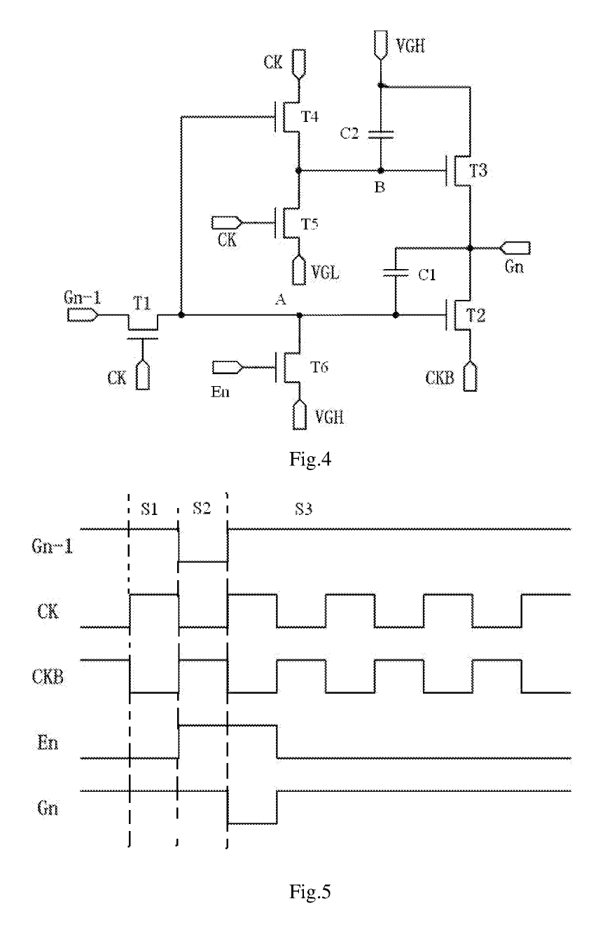

In the shift register unit according to the embodiments of the present disclosure, the control transistor T6 is connected to the gate electrode of the output transistor T2, and the gate electrode of the control transistor T6 is controlled by the control signal En from an emission Gate On Array (GOA) driver circuit in a current row. For the shift register unit including the P-type transistors, as shown in FIG. 5, at the reset stage, the control signal En is a long, low-level signal. A rising edge of the control signal En is one clock cycle earlier than a falling edge of the gate driving signal from the current-level gate driving signal output end Gn, and a falling edge of the control signal En is at an identical position to the falling edge of the gate driving signal from the current-level gate driving signal output end Gn.

As shown in FIG. 5, during the operation of the shift register unit in FIG. 4, at the input stage S1, Gn-1 is at a low level, CK is at a low level, CKB is at a high level, and En and Gn are both at a high level. At this time, T1 is turned on, and Gn-1 is inputted to the output control node A through T1, so that the output control node A is at a low level. T2, T4 and T5 are all turned on, and T6 is turned off, so that the reset control node B is at a low level. T3 is also turned on, so Gn outputs a high level.

At the output stage S2, Gn-1 is at a high level, CK is at a high level, CKB is at a low level, En is at a high level, and Gn is at a low level. At this time, T5 and T6 are turned off, so that the output control node A is maintained at a low level. T2 and T4 are turned on, and Gn outputs a low level, so that the reset control node B is at a high level, and T3 is turned off.

At the reset stage S3, Gn-1 is at a high level, En is at a low level, and CK and CKB are at a high level and a low level alternately. Because En is at the low level, the output control node A is at a high level at the reset stage S3. T2 and T4 are turned off, and in the case that the CK is at the low level, T5 is turned on, so that the reset control node B is maintained at a low level. T3 is maintained in an on state at the reset stage, and Gn outputs a high level.

Based on the above-mentioned operation procedure of the shift register unit in FIG. 4, at the reset stage S3, T1 is turned off in the case that CK is at a high level. At this time, T6 is still in the on state, so the gate electrode of T2 may be maintained at the high level VGH, i.e., the gate electrode of T2 may be maintained at the same potential due to the existence of T6. As a result, it is able to maintain T2 in the off state at the reset stage.

The present disclosure further provides in some embodiments a method for driving the above-mentioned shift register unit, including a step of enabling the control module to turn off the output module at the reset stage.

According to the driving method in the embodiments of the present disclosure, the output module is turned off at the reset stage under the control of the control module, so as to output the gate driving signal in a stable manner.

The present disclosure further provides in some embodiments a gate driver circuit including multiple levels of the above-mentioned shift register units. Apart from a first-level shift register unit, an input end of a current-level shift register unit is connected to a gate driving signal output end of a previous-level shift register unit.

The present disclosure further provides in some embodiments a display device including the above-mentioned gate driver circuit.

The above are merely the preferred embodiments of the present disclosure. Obviously, a person skilled in the art may make further modifications and improvements without departing from the spirit of the present disclosure, and these modifications and improvements shall also fall within the scope of the present disclosure.

1. A shift register unit, comprising:
a gate driving signal output end;
an output module configured to control the gate driving signal output end, so as to output an invalid signal at an input stage and output a valid signal at an output stage; and
a control module configured to turn off the output module at a reset stage.

2. The shift register unit according to claim 1, wherein
a control end of the output module is connected to an output control node, and
the shift register unit further comprises:
an input module configured to input an input signal to the output control node at the input stage and maintain a potential at the output control node at the output stage; and
a reset module connected to the output control node and the gate driving signal output end and configured to control the gate driving signal output end to output the invalid signal at the reset stage.

3. The shift register unit according to claim 2, wherein
the control module comprises a control transistor, wherein a gate electrode of the control transistor is configured to receive a control signal, a first electrode of the control transistor is connected to the output control node, and a second electrode of the control transistor is configured to receive a first level; and
the control signal is used to turn off the control transistor at the input stage and the output stage, and turn on the control transistor at the reset stage.

4. The shift register unit according to claim 3, wherein the input module comprises an input transistor, wherein a gate electrode of the input transistor is configured to receive a first clock signal, a first electrode of the input transistor is configured to receive the input signal, and a second electrode of the input transistor is connected to the output control node.

5. The shift register unit according to claim 4, wherein the output module comprises:
an output transistor, wherein a gate electrode of the output transistor is connected to the output control node, a first electrode of the output transistor is connected to the gate driving signal output end, and a second electrode of the output transistor is configured to receive a second clock signal with a phase reverse to the first clock signal; and
a first capacitor connected between the gate electrode of the output transistor and the gate driving signal output end.

6. The shift register unit according to claim 1, wherein the reset module comprises:
a reset transistor, wherein a gate electrode of the reset transistor is connected to a reset control node, a first electrode of the reset transistor is configured to receive the first level, and a second electrode of the reset transistor is connected to the gate driving signal output end;
a first reset control transistor, wherein a gate electrode of the first reset control transistor is connected to the output control node, a first electrode of the first reset control transistor is configured to receive the first clock signal, and a second electrode of the first reset control transistor is connected to the reset control node;
a second reset control transistor, wherein a gate electrode of the second reset control transistor is configured to receive the first clock signal, a first electrode of the second reset control transistor is connected to the reset control node, and a second electrode of the second reset control transistor is configured to receive a second level; and
a second capacitor, wherein a first end of the second capacitor is connected to the reset control node, and a second end of the second capacitor is configured to receive the first level.

7. The shift register unit according to claim 6, wherein
the first electrode of each of the transistors is a source electrode and the second electrode of the transistor is a drain electrode, or
the first electrode of each of the transistors is a drain electrode and the second electrode of the transistor is a source electrode.

8. A method for driving the shift register unit according to claim 1, comprising a step of enabling the control module to turn off the output module at the reset stage.

9. A gate driver circuit comprising multiple levels of the shift register units, each of the shift register units is the shift register unit according to claim 1, wherein apart from a first-level shift register unit, an input end of a current-level shift register unit is connected to a gate driving signal output end of a previous-level shift register unit.

10. A display device, comprising the gate driver circuit according to claim 9.

11. The shift register unit according to claim 2, wherein the reset module comprises:
a reset transistor, wherein a gate electrode of the reset transistor is connected to a reset control node, a first electrode of the reset transistor is configured to receive the first level, and a second electrode of the reset transistor is connected to the gate driving signal output end;
a first reset control transistor, wherein a gate electrode of the first reset control transistor is connected to the output control node, a first electrode of the first reset control transistor is configured to receive the first clock signal, and a second electrode of the first reset control transistor is connected to the reset control node;
a second reset control transistor, wherein a gate electrode of the second reset control transistor is configured to receive the first clock signal, a first electrode of the second reset control transistor is connected to the reset control node, and a second electrode of the second reset control transistor is configured to receive a second level; and
a second capacitor, wherein a first end of the second capacitor is connected to the reset control node, and a second end of the second capacitor is configured to receive the first level.

12. The shift register unit according to claim 3, wherein the reset module comprises:
a reset transistor, wherein a gate electrode of the reset transistor is connected to a reset control node, a first electrode of the reset transistor is configured to receive the first level, and a second electrode of the reset transistor is connected to the gate driving signal output end;
a first reset control transistor, wherein a gate electrode of the first reset control transistor is connected to the output control node, a first electrode of the first reset control transistor is configured to receive the first clock signal, and a second electrode of the first reset control transistor is connected to the reset control node;
a second reset control transistor, wherein a gate electrode of the second reset control transistor is configured to receive the first clock signal, a first electrode of the second reset control transistor is connected to the reset control node, and a second electrode of the second reset control transistor is configured to receive a second level; and
a second capacitor, wherein a first end of the second capacitor is connected to the reset control node, and a second end of the second capacitor is configured to receive the first level.

13. The shift register unit according to claim 4, wherein the reset module comprises:
a reset transistor, wherein a gate electrode of the reset transistor is connected to a reset control node, a first electrode of the reset transistor is configured to receive the first level, and a second electrode of the reset transistor is connected to the gate driving signal output end;
a first reset control transistor, wherein a gate electrode of the first reset control transistor is connected to the output control node, a first electrode of the first reset control transistor is configured to receive the first clock signal, and a second electrode of the first reset control transistor is connected to the reset control node;
a second reset control transistor, wherein a gate electrode of the second reset control transistor is configured to receive the first clock signal, a first electrode of the second reset control transistor is connected to the reset control node, and a second electrode of the second reset control transistor is configured to receive a second level; and
a second capacitor, wherein a first end of the second capacitor is connected to the reset control node, and a second end of the second capacitor is configured to receive the first level.

14. The shift register unit according to claim 5, wherein the reset module comprises:
a reset transistor, wherein a gate electrode of the reset transistor is connected to a reset control node, a first electrode of the reset transistor is configured to receive the first level, and a second electrode of the reset transistor is connected to the gate driving signal output end;
a first reset control transistor, wherein a gate electrode of the first reset control transistor is connected to the output control node, a first electrode of the first reset control transistor is configured to receive the first clock signal, and a second electrode of the first reset control transistor is connected to the reset control node;
a second reset control transistor, wherein a gate electrode of the second reset control transistor is configured to receive the first clock signal, a first electrode of the second reset control transistor is connected to the reset control node, and a second electrode of the second reset control transistor is configured to receive a second level; and
a second capacitor, wherein a first end of the second capacitor is connected to the reset control node, and a second end of the second capacitor is configured to receive the first level.

15. The gate driver circuit according to claim 9, wherein
a control end of the output module is connected to an output control node, and
the shift register unit further comprises:
an input module configured to input an input signal to the output control node at the input stage and maintain a potential at the output control node at the output stage; and
a reset module connected to the output control node and the gate driving signal output end and configured to control the gate driving signal output end to output the invalid signal at the reset stage.

16. The gate driver circuit according to claim 15, wherein
the control module comprises a control transistor, wherein a gate electrode of the control transistor is configured to receive a control signal, a first electrode of the control transistor is connected to the output control node, and a second electrode of the control transistor is configured to receive a first level; and
the control signal is used to turn off the control transistor at the input stage and the output stage, and turn on the control transistor at the reset stage.

17. The gate driver circuit according to claim 16, wherein the input module comprises an input transistor, wherein a gate electrode of the input transistor is configured to receive a first clock signal, a first electrode of the input transistor is configured to receive the input signal, and a second electrode of the input transistor is connected to the output control node.

18. The gate driver circuit according to claim 17, wherein the output module comprises:
an output transistor, wherein a gate electrode of the output transistor is connected to the output control node, a first electrode of the output transistor is connected to the gate driving signal output end, and a second electrode of the output transistor is configured to receive a second clock signal with a phase reverse to the first clock signal; and
a first capacitor connected between the gate electrode of the output transistor and the gate driving signal output end.

19. The gate driver circuit according to claim 9, wherein the reset module comprises:
a reset transistor, wherein a gate electrode of the reset transistor is connected to a reset control node, a first electrode of the reset transistor is configured to receive the first level, and a second electrode of the reset transistor is connected to the gate driving signal output end;
a first reset control transistor, wherein a gate electrode of the first reset control transistor is connected to the output control node, a first electrode of the first reset control transistor is configured to receive the first clock signal, and a second electrode of the first reset control transistor is connected to the reset control node;
a second reset control transistor, wherein a gate electrode of the second reset control transistor is configured to receive the first clock signal, a first electrode of the second reset control transistor is connected to the reset control node, and a second electrode of the second reset control transistor is configured to receive a second level; and
a second capacitor, wherein a first end of the second capacitor is connected to the reset control node, and a second end of the second capacitor is configured to receive the first level.

20. The display device according to claim 10, wherein
a control end of the output module is connected to an output control node, and
the shift register unit further comprises:
an input module configured to input an input signal to the output control node at the input stage and maintain a potential at the output control node at the output stage; and
a reset module connected to the output control node and the gate driving signal output end and configured to control the gate driving signal output end to output the invalid signal at the reset stage.
